(19) United States
(12) Patent Application Publication
(10) Pub. No.: US 2025/0218067 A1
(43) Pub. Date: Jul. 3, 2025

(54) SYSTEMS AND METHODS FOR MAGNETIC RESONANCE IMAGE RECONSTRUCTION WITH NONCONVEX SINGLE VALUE DECOMPOSITION

(71) Applicant: University of Virginia Patent Foundation, Charlottesville, VA (US)

(72) Inventors: Kang Yan, Charlottesville, VA (US); Zhixing Wang, Charlottesville, VA (US); Quan Dou, Charlottesville, VA (US); Sheng Chen, Charlottesville, VA (US); Craig H. Meyer, Charlottesville, VA (US)

(21) Appl. No.: 18/642,754

(22) Filed: Apr. 22, 2024

Related U.S. Application Data
(60) Provisional application No. 63/467,259, filed on May 17, 2023.
(60) Provisional application No. 63/460,684, filed on Apr. 20, 2023.

(51) Int. Cl. G06T 11/00; G01R 33/48; G01R 33/56; G06T 5/60; G06T 5/70

(52) U.S. Cl. CPC G06T 11/006; G01R 33/482; G01R 33/5608; G06T 5/60; G06T 5/70; G06T 2207/10088; G06T 2207/20048; G06T 2207/20081; G06T 2207/20084; G06T 2207/30004; G06T 2210/41; G06T 2211/424; G06T 2211/441

(57) ABSTRACT

A computer implemented method of reconstructing magnetic resonance images (MRI) in Cartesian coordinates uses acquired magnetic resonance data and implements a Fourier transform to place the MRI data in k-space. The method allows for under-sampling the k-space and achieving an accurate output image by selecting an image model to map the sampled data and iteratively converge the model to an output that matches a region of interest subject to the MRI. The image model may be an alternating direction method of multipliers (ADMM) or an ADMM with non-convex low rank regularization algorithm. A de-noising algorithm may be at least one of a plug and play block matching and 3D filtering (PnP-BM3D), a plug and play weighted nuclear norm minimization (WNNM), or a plug and play denoising convolutional neural networks (PnP-DnCNN) algorithm. An iterative optimization of the variables of the model yields an output image.

### CROSS-REFERENCE TO RELATED APPLICATIONS

This application claims priority to and the benefit of U.S. provisional patent application No. 63/460,684, filed on Apr. 20, 2023, and titled Method and System for Applying Advanced Denoisers to Enhance Highly Under-Sampled MRI Reconstruction Under Plug-and-Play ADMM Framework the disclosure of which is hereby incorporated by reference herein in its entirety.

This application also claims priority to and the benefit of U.S. provisional patent application No. 63/467,259, filed on May 17, 2023, and titled System and Method for Accelerated Parameter Mapping in the k-p Domain Via Nonconvex Low Rank Constraint the disclosure of which is hereby incorporated by reference herein in its entirety.

### STATEMENT OF GOVERNMENT RIGHTS

This invention was made with government support under grant number EB028773 awarded by the National Institutes of Health. The government has certain rights in the invention.

### BACKGROUND

Sparse sampling techniques for magnetic resonance imaging (MRI) reconstruction has been improving over the years, yet work remains to be done. At least one earlier work by Zhao [17], incorporated by reference herein, discusses techniques for sparse sampling in the k-parametric domain, i.e., k-p space. Zhao proposed simultaneously utilizing low rank and sparse components of the k-space domain to allow reconstruction of images with a convex optimization problem across different parameters for MRI data collection. The convex optimization problem is reduced to a one dimensional problem in Zhao's configuration, but Zhao's method still relies upon estimating the parameter subspace, which can lead to errors.

In other advances, Guillemot, et al. [24], incorporated herein by reference, uses singular value decomposition (SVD) to take advantage of data sparsification with different constraints to make the calculation of projecting constraints onto a convex data set. With appropriate care to using sparse data, Guillemot's procedure can converge to an optimal solution with less data, and this kind of SVD algorithm may apply to MRI reconstruction. Lyra-Leite [25], incorporated by reference herein, explains how SVD calculations can apply to MRI, which is also described in regard to the strong magnetic field B0, gradient coils (i.e., Gx, Gy, Gz) that produce the gradient perturbation of B0 and frequency encode or phase encode the x, y, z spatial positions in any given scan image. A radio-frequency coil sends an excitation pulse to the imaging subject's body to yield net magnetization in an x-y plane for imaging in layers. The rotating magnetization generates an oscillating signal that can be detected. The frequency and phase of that oscillating signal can be detected for reconstructing the images of the energized region of interest. The resulting k-space of frequency or phase encoded data must be sampled and decomposed to give values to pixels or voxels of an image. Lyra-Leite [25] utilizes single value decomposition to reconstruct the images from less sample points within the encoded k-space maps.

These prior methods, however, need improvements in accuracy, signal to noise ratio, and overall quality of reconstruction.

In some embodiments, artificial intelligence and machine learning techniques are utilized to reconstruct MRI data into images that are useful to the naked eye. Machine Learning (ML) and Artificial Intelligence (AI) systems are in widespread use in customer service, marketing, and other industries. Machine learning is considered a subset of more general artificial intelligence operations, and AI endeavors may utilize numerous instances of machine learning to make decisions, predict outputs, and perform human-like intelligent operations. Machine learning protocols typically involve programming a model that instantiates an appropriate algorithm for a given computing environment and training the model on a particular data set or domain with known historical results. The results are generally known outputs of many combinations of parameter values that the algorithm accesses during training. The model uses numerous statistical and mathematical operations to learn how to make logical decisions and generate new outputs based on the historical training data. Machine learning (ML) includes, but is not limited to, a number of models such as neural networks, deep learning algorithms, support vector machines, data clustering, regression models, and Monte Carlo simulations. Other models may utilize linear regression, logistic regression, support vector machines, K-means clustering, classification models such as a binary classifier or a multi-class classifier, clustering models, anomaly detection, other supervised learning models, and even combinations of one or more machine language model types. Most of these take vectors of data as inputs.

The term “artificial intelligence,” therefore, includes any technique that enables one or more computing devices or comping systems (i.e., a machine) to mimic human intelligence. Artificial intelligence (AI) includes, but is not limited to, knowledge bases, machine learning, representation learning, and deep learning. The term “machine learning” is generally a subset of AI that enables a machine to acquire knowledge by extracting patterns from raw data.

The term “representation learning” may be used as a subset of machine learning that enables a machine to automatically discover representations needed for feature detection, prediction, or classification from raw data. Representation learning techniques include, but are not limited to, autoencoders.

The term “deep learning” may also be considered a subset of machine learning that enables a machine to automatically discover representations needed for feature detection, prediction, classification, etc. using layers of processing. Deep learning techniques include, but are not limited to, artificial neural network or multilayer perceptron (MLP).

Machine learning models include supervised, semi-supervised, and unsupervised learning models. In a supervised learning model, the model learns a function that maps an input (also known as feature or features) to an output (also known as target or target) during training with a labeled data set (or dataset). In an unsupervised learning model, the model learns a function that maps an input (also known as feature or features) to an output (also known as target or target) during training with an unlabeled data set. In a semi-supervised model, the model learns a function that maps an input (also known as feature or features) to an output (also known as target or target) during training with both labeled and unlabeled data.

Some machine learning models are designed for a specific data set or domain and are highly expert at handling the nuances within that narrow domain. It is with respect to these and other considerations that the various aspects of the present disclosure as described below are presented.

### SUMMARY

Other aspects and features according to the example embodiments of the disclosed technology will become apparent to those of ordinary skill in the art, upon reviewing the following detailed description in conjunction with the accompanying figures.

A computer implemented method of reconstructing magnetic resonance images (MRI) in Cartesian coordinates uses acquired magnetic resonance data and implements a Fourier transform to place the MRI data in k-space. The method allows for under-sampling the k-space and achieving an accurate output image by selecting an image model to map the sampled data and iteratively converge the model to an output that matches a region of interest subject to the MRI. The image model may be an alternating direction method of multipliers (ADMM) or an ADMM with non-convex low rank regularization algorithm. A de-noising algorithm may be at least one of a plug and play block matching and 3D filtering (PnP-BM3D), a plug and play weighted nuclear norm minimization (WNNM), or a plug and play denoising convolutional neural networks (PnP-DnCNN) algorithm. An iterative optimization of the variables of the model yields an output image.

### BRIEF DESCRIPTION OF THE DRAWINGS

Reference will now be made to the accompanying drawings, which are not necessarily drawn to scale. The patent or application file contains at least one drawing executed in color. Copies of this patent or patent application publication with color drawing(s) will be provided by the Office upon request and payment of the necessary fee.

FIG. 1 is a system diagram illustrating an imaging system capable of implementing aspects of the present disclosure in accordance with one or more embodiments.

FIG. 2 is a diagram showing an example embodiment of a system with thermal therapy used with MRI, which is capable of implementing aspects of the present disclosure in accordance with one or more embodiments.

FIG. 3 is a computer architecture diagram showing a computing system capable of implementing aspects of the present disclosure in accordance with one or more embodiments.

FIG. 4 is a flow diagram showing operations of a method for converging a selected data model for the magnetic resonance image data.

FIG. 5 illustrates a flowchart of the PnP framework. D(x) represents the denoising algorithm.

FIG. 6 illustrates diagrams of the plug and play block matching and 3D filtering (PnP-BM3D), plug and play weighted nuclear norm minimization (WNNM), and plug and play denoising convolutional neural networks (PnP-DnCNN) algorithms used in the PnP denoising step.

FIG. 7 illustrates reconstructed images, peak signal to noise ratios (PSNR) and structural similarity index measures (SSIM) using different reconstruction methods with four-fold under-sampled k-space data.

FIG. 8A is a plot of PSNRs vs. the number of iterations for L1 Eigenvector-Based SPIRIT (L1-ESPIRIT), plug and play block matching and 3D filtering (PnP-BM3D), plug and play weighted nuclear norm minimization (WNNM), and plug and play denoising convolutional neural networks (PnP-DnCNN).

FIG. 8B is a plot of SSIM vs. the number of iterations for L1 Eigenvector-Based SPIRIT (L1-ESPIRIT), plug and play block matching and 3D filtering (PnP-BM3D), plug and play weighted nuclear norm minimization (WNNM), and plug and play denoising convolutional neural networks (PnP-DnCNN).

FIG. 9 illustrates the ADMM framework to solve the nonconvex low rank regularization.

FIG. 10 illustrates T2w kidney images reconstructed from retrospectively under-sampled data at acceleration rates of 3 and 6 using different reconstruction methods. The proposed method achieves lower normalized root mean square error (NRMSE) than the alternative techniques. Black arrows point to regions where the proposed method better recovers details of T2w images.

FIG. 11A shows normalized root mean square error (NRMSE) performance of T2w images reconstructed using compressed sensing (CS), low rank and sparse sampling (L&S) and non-local low-rank regularization (NLR) at under-sampled rates R=3, 4, 5, and 6.

FIG. 11B shows the structural similarity index (SSIM) performance among compressed sensing (CS), low rank and sparse sampling (L&S) and non-local low-rank regularization (NLR).

FIG. 11C displays the under-sampling patterns at different acceleration factors.

FIG. 12A shows a comparison of the results of T2 mapping using CS, L&S and NLR. FIG. 12A also shows the calculated T2 maps and selected ROI for quantitative analysis.

FIG. 12B displays the statistical results using Bland-Altman analysis and linear regression between the T2 maps estimated from CS, L&S and NLR vs. the reference T2 maps. NLR has stronger positive correlation than CS and L&S.

FIG. 13A illustrates a comparison of the results of T2* mapping using CS, L&S and NLR. FIG. 13A also shows the calculated T2 maps and selected ROI for quantitative analysis.

FIG. 13B displays the statistics results using Bland-Altman analysis and linear regression between the T2 maps estimated from CS, L&S and NLR vs. the reference T2 maps. NLR has stronger positive correlation than CS and L&S.

FIG. 14 shows a Formula Table for complex formulas referred to herein.

### DETAILED DESCRIPTION

In some aspects, the disclosed technology relates to systems, methods, and computer-readable medium for magnetic resonance based skull thermometry. Although example embodiments of the disclosed technology are explained in detail herein, it is to be understood that other embodiments are contemplated. Accordingly, it is not intended that the disclosed technology be limited in its scope to the details of construction and arrangement of components set forth in the following description or illustrated in the drawings. The disclosed technology is capable of other embodiments and of being practiced or carried out in various ways.

It must also be noted that, as used in the specification and the appended claims, the singular forms “a,” “an” and “the” include plural referents unless the context clearly dictates otherwise. Ranges may be expressed herein as from “about” or “approximately” one particular value and/or to “about” or “approximately” another particular value. When such a range is expressed, other exemplary embodiments include from the one particular value and/or to the other particular value.

By “comprising” or “containing” or “including” is meant that at least the named compound, element, particle, or method step is present in the composition or article or method, but does not exclude the presence of other compounds, materials, particles, method steps, even if the other such compounds, material, particles, method steps have the same function as what is named.

In describing example embodiments, terminology will be resorted to for the sake of clarity. It is intended that each term contemplates its broadest meaning as understood by those skilled in the art and includes all technical equivalents that operate in a similar manner to accomplish a similar purpose. It is also to be understood that the mention of one or more steps of a method does not preclude the presence of additional method steps or intervening method steps between those steps expressly identified. Steps of a method may be performed in a different order than those described herein without departing from the scope of the disclosed technology. Similarly, it is also to be understood that the mention of one or more components in a device or system does not preclude the presence of additional components or intervening components between those components expressly identified.

As discussed herein, a “subject” (or “patient”) may be any applicable human, animal, or other organism, living or dead, or other biological or molecular structure or chemical environment, and may relate to particular components of the subject, for instance specific organs, tissues, or fluids of a subject, may be in a particular location of the subject, referred to herein as an “area of interest” or a “region of interest.”

A detailed description of aspects of the disclosed technology, in accordance with various example embodiments, will now be provided with reference to the accompanying drawings. The drawings form a part hereof and show, by way of illustration, specific embodiments and examples. In referring to the drawings, like numerals represent like elements throughout the several figures.

Embodiments of the present disclosure include MRI-based thermometry techniques. In some embodiments of the present disclosure, the MRI-based thermometry technique is adapted to measure heating in the skull of a human patient during a focused ultrasound (FUS) treatment.

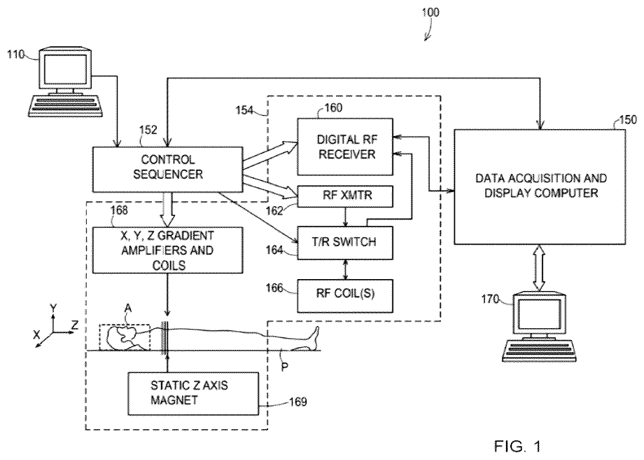

FIG. 1 is a system diagram illustrating an imaging system capable of implementing aspects of the present disclosure in accordance with one or more example embodiments. FIG. 1 illustrates an example of a magnetic resonance imaging (MRI) system 100, including a data acquisition and display computer 150 coupled to an operator console 110, an MRI real-time control sequencer 152, and an MRI subsystem 154. The MRI subsystem 154 may include XYZ magnetic gradient coils and associated amplifiers 168, a static Z-axis magnet 169, a digital RF transmitter 162, a digital RF receiver 160, a transmit/receive switch 164, and RF coil(s) 166. The MRI subsystem 154 may be controlled in real time by control sequencer 152 to generate magnetic and radio frequency fields that stimulate magnetic resonance phenomena in a subject P to be imaged, for example to implement magnetic resonance imaging sequences in accordance with various embodiments of the present disclosure. Reconstructed images, such as contrast-enhanced image(s) of an area of interest A of the subject P may be shown on display 170.

The area of interest A shown in the example embodiment of FIG. 1 corresponds to a head region of subject P, but it should be appreciated that the area of interest for purposes of implementing various aspects of the disclosure presented herein is not limited to the head area. It should be recognized and appreciated that the area of interest in various embodiments may encompass various areas of subject P associated with various physiological characteristics, such as, but not limited to the head and brain region, chest region, heart region, abdomen, upper or lower extremities, or other organs or tissues. Various aspects of the present disclosure are described herein as being implemented on portions of the skeletal system of human subjects, for example cortical bone tissue.

It should be appreciated that any number and type of computer-based medical imaging systems or components, including various types of commercially available medical imaging systems and components, may be used to practice certain aspects of the present disclosure. Systems as described herein with respect to imaging are not intended to be specifically limited to the particular system shown in FIG. 1. Likewise, systems as described herein with respect to the application of localized energy for heating certain areas for thermal treatment are not intended to be specifically limited to the particular systems shown or described below.

One or more data acquisition or data collection steps as described herein in accordance with one or more embodiments may include acquiring, collecting, receiving, or otherwise obtaining data such as imaging data corresponding to an area of interest. By way of example, data acquisition or collection may include acquiring data via a data acquisition device, receiving data from an on-site or off-site data acquisition device or from another data collection, storage, or processing device. Similarly, data acquisition or data collection devices of a system in accordance with one or more embodiments of the present disclosure may include any device configured to acquire, collect, or otherwise obtain data, or to receive data from a data acquisition device within the system, an independent data acquisition device located on-site or off-site, or another data collection, storage, or processing device.

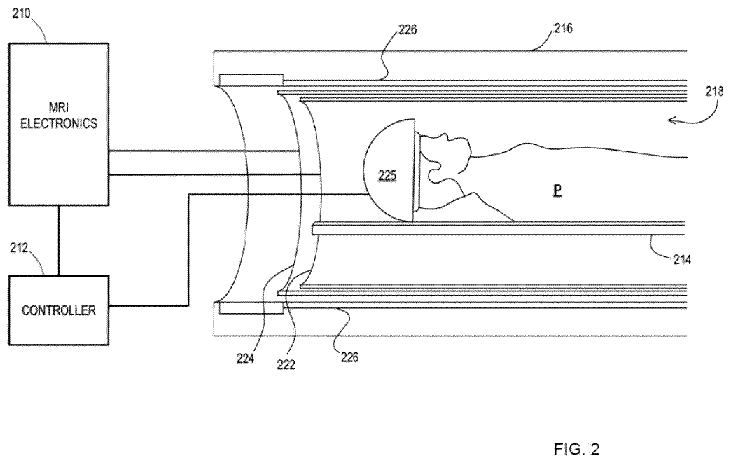

FIG. 2 is a diagram showing an embodiment of a system with focused ultrasound (FUS) used with MRI, each of which is capable of implementing aspects of the present disclosure in accordance with one or more embodiments. The MRI system may comprise one or more components of the system 100 shown in FIG. 1. As shown, RF coils 222, gradient coils 224, static Z axis magnet 226, and magnetic housing 216 surround the patient P when the patient is positioned on the table 214 inside of the MRI bore 218. A controller 212 communicates with MRI system electronics 210 as well as the FUS device (225). The MRI system electronics 210 can include one or more components of the MRI subsystem 154 shown in FIG. 23. A user computer (not shown) may communicate with the controller 212 for control of the MRI system and FUS device functions.

In FIG. 2, a type of FUS device 225 surrounds the patient's head, as may be used for thermal therapy applied to tissues of or near the brain. The device 225 may have multiple ultrasound transducers for applying focused energy to particular target areas of interest of the head of the patient.

The device 225 can be configured to apply localized energy to heat a targeted region within the area of interest A which includes tissues of or near the brain. As a result, heating may occur in bone tissues, such as that of the skull. The MRI components of the system (including MRI electronics 210) are configured to work within a larger MRI system to acquire magnetic resonance data and for reconstructing images of all or regions of the area of interest as well as temperature-related data. The temperature data may include a temperature at a targeted region and/or a temperature at a reference region. The temperature data may be used to monitor the effectiveness and safety of the thermal therapy treatment and adjust treatment settings accordingly.

The targeted region may include bone tissue, which as described above, has a short T2/T2*. Control of the application of the focused energy via the controller 212 may be managed by an operator using an operator console (e.g., user computer). The controller 212 (which, as shown is also coupled to MRI electronics 210) may also be configured to manage functions for the application and/or receiving of MR signals. For example, the controller 212 may be coupled to a control sequencer such as the control sequencer 152 shown in FIG. 1.

Although the FUS device 225 shown in the embodiment of FIG. 2 utilize ultrasound transducer(s) as the source for delivering localized energy to an area of interest, it should be appreciated that other types of devices may alternatively be used without departing from the patentable scope of the present disclosure. Other possible types of thermal treatment/application devices that may be utilized include laser and/or RF ablation devices, or other devices adapted to heat a target tissue.

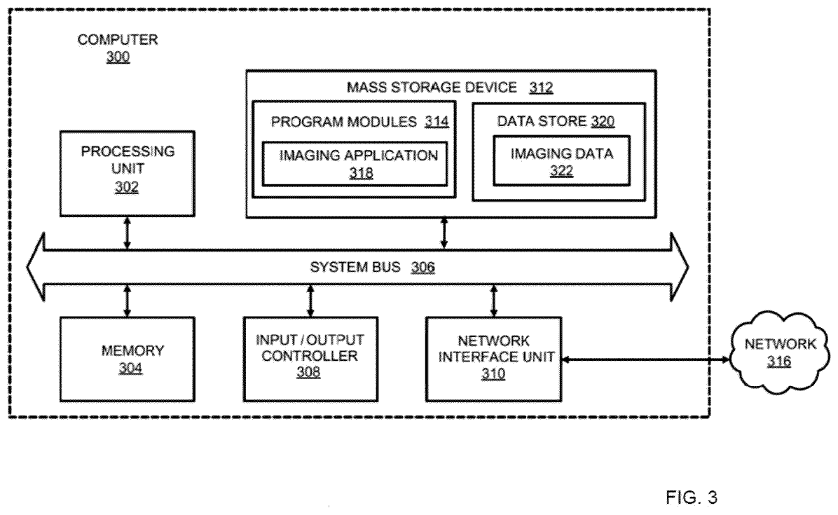

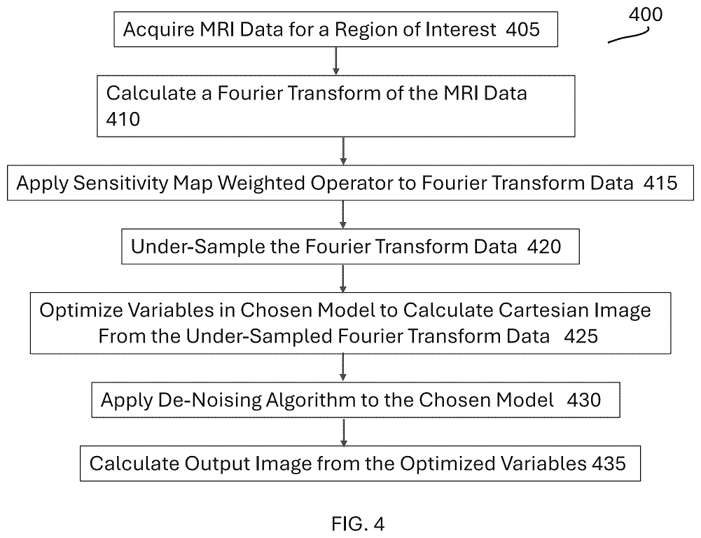

FIG. 3 is a computer architecture diagram showing a computing system capable of implementing aspects of the present disclosure in accordance with one or more embodiments described herein. A computer 300 may be configured to perform one or more specific steps of a method and/or specific functions for a system. The computer may be configured to perform one or more functions associated with embodiments illustrated in one or more of the figures herein. For example, the computer 300 may be configured to perform aspects described herein for implementing the pulse sequences shown and for various aspects of magnetic resonance imaging and related signal and temperature monitoring shown in the figures. It should be appreciated that the computer 300 may be implemented within a single computing device or a computing system formed with multiple connected computing devices. The computer 300 may be configured to perform various distributed computing tasks, in which processing and/or storage resources may be distributed among the multiple devices. The data acquisition and display computer 150 and/or operator console 110 of the system shown in FIG. 1, and the controller 212 and/or MRI electronics 210 of the system shown in FIG. 2, may include one or more components of the computer 300.

As shown, the computer 300 includes a processing unit 302 (“CPU”), a system memory 304, and a system bus 306 that couples the memory 304 to the CPU 302. The computer 300 further includes a mass storage device 312 for storing program modules 314. The program modules 314 may be operable to perform functions associated with one or more embodiments described herein. For example, when executed, the program modules can cause one or more medical imaging devices, localized energy producing devices, and/or computers to perform functions described herein for implementing the pulse sequence shown in FIG. 3, the method shown in FIG. 1, and for various aspects of magnetic resonance imaging and related signal and temperature monitoring and analysis shown in the figures herein. The program modules 314 may include an imaging application 318 for performing data acquisition and/or processing functions as described herein, for example to acquire and/or process image data corresponding to magnetic resonance imaging of an area of interest. The computer 300 can include a data store 320 for storing data that may include imaging-related data 322 such as acquired data from the implementation of magnetic resonance imaging pulse sequences in accordance with various embodiments of the present disclosure.

The mass storage device 312 is connected to the CPU 302 through a mass storage controller (not shown) connected to the bus 306. The mass storage device 312 and its associated computer-storage media provide non-volatile storage for the computer 300. Although the description of computer-storage media contained herein refers to a mass storage device, such as a hard disk, it should be appreciated by those skilled in the art that computer-storage media can be any available computer storage media that can be accessed by the computer 300.

By way of example and not limitation, computer storage media (also referred to herein as “computer-readable storage medium” or “computer-readable storage media”) may include volatile and non-volatile, removable and non-removable media implemented in any method or technology for storage of information such as computer-storage instructions, data structures, program modules, or other data. For example, computer storage media includes, but is not limited to, RAM, ROM, EPROM, EEPROM, flash memory or other solid state memory technology, CD-ROM, digital versatile disks (“DVD”), HD-DVD, BLU-RAY, or other optical storage, magnetic cassettes, magnetic tape, magnetic disk storage or other magnetic storage devices, or any other medium which can be used to store the desired information and which can be accessed by the computer 300. “Computer storage media”, “computer-readable storage medium” or “computer-readable storage media” as described herein do not include transitory signals.

According to various embodiments, the computer 300 may operate in a networked environment using connections to other local or remote computers through a network 316 via a network interface unit 310 connected to the bus 306. The network interface unit 310 may facilitate connection of the computing device inputs and outputs to one or more suitable networks and/or connections such as a local area network (LAN), a wide area network (WAN), the Internet, a cellular network, a radio frequency (RF) network, a Bluetooth-enabled network, a Wi-Fi enabled network, a satellite-based network, or other wired and/or wireless networks for communication with external devices and/or systems.

The computer 300 may also include an input/output controller 308 for receiving and processing input from any of a number of input devices. Input devices may include one or more of keyboards, mice, stylus, touchscreens, microphones, audio capturing devices, and image/video capturing devices. An end user may utilize the input devices to interact with a user interface, for example a graphical user interface, for managing various functions performed by the computer 300. The input/output controller 308 may be configured to manage output to one or more display devices for displaying visually representations of data, such as display monitors/screens that are integral with other components of the computer 300 or are remote displays.

The bus 306 may enable the processing unit 302 to read code and/or data to/from the mass storage device 312 or other computer-storage media. The computer-storage media may represent apparatus in the form of storage elements that are implemented using any suitable technology, including but not limited to semiconductors, magnetic materials, optics, or the like. The computer-storage media may represent memory components, whether characterized as RAM, ROM, flash, or other types of technology. The computer storage media may also represent secondary storage, whether implemented as hard drives or otherwise. Hard drive implementations may be characterized as solid state, or may include rotating media storing magnetically-encoded information. The program modules 314, which include the imaging application 318, may include instructions that, when loaded into the processing unit 302 and executed, cause the computer 300 to provide functions associated with one or more embodiments illustrated in the figures. The program modules 314 may also provide various tools or techniques by which the computer 300 may participate within the overall systems or operating environments using the components, flows, and data structures discussed throughout this description.

Accelerating MRI acquisition is always in high demand, because long scan times could increase the potential risk of image degradation caused by patient motion. Generally, MRI reconstruction with higher under-sampling rates requires regularization terms, such as wavelet transformation and total variation transformation. This disclosure investigates employing the plug and play (PnP) alternating direction method of multipliers (ADMM)) framework to reconstruct highly under-sampled MRI k-space data with three different denoiser algorithms: block matching and 3D filtering (BM3D), weighted nuclear norm minimization (WNNM) and residual learning of deep learning, de-noising convolutional neural networks CNN (DnCNN). The results show that these three PnP-based methods outperform current regularization methods.

One challenge of fast MRI is to recover the original image from under-sampled k-space data. Prior technologies, such as SENSE [1] exploits the knowledge of sensitivity maps, and GRAPPA [2] uses the learned weighted-coefficients from autocalibration signal (ACS) lines to estimate the missing k-space lines. Compressed sensing (CS) [3] uses the idea that data could be compressed if under-sampled artifacts are incoherent. Therefore, it introduces the concept of sparsity, achieved by regularization terms. L1-ESPIRIT [4] also includes regularization terms in soft-SENSE reconstruction to iteratively find the optimal solution. After the PnP prior [5] was first proposed by Venkatakrishnan et al., there have been several studies applying this concept to MRI [6, 7]. Most of these studies focus on the convolutional neural network, CNN, algorithm to complete the denoising process of the PnP algorithm. Alternatively, DnCNN [8] may be a better fit. In non-limiting embodiments, this work explores three advanced denoiser algorithms to reconstruct four-fold under-sampled MRI data using the PnP-ADMM framework. The idea behind BM3D [9] is that given a local patch, it is not difficult to find many similar patches from nearby. These patches help with denoising, and this idea is typically true for medical images. The human brain, for example, has white matter, gray matter and cerebrospinal fluid, and thus has large non-local self-similarity in this sense. WNNM aims to improve conventional low rank algorithms by differently weighting singular values in nuclear norm, compared to the general solution which treats singular values equally in order to meet the convex property. Instead of directly outputting a denoised image, DnCNN learns a residual image, and this residual learning and batch normalization could benefit from each other, further improving the denoising performance. This neural network is more natural to combine with the PnP framework.

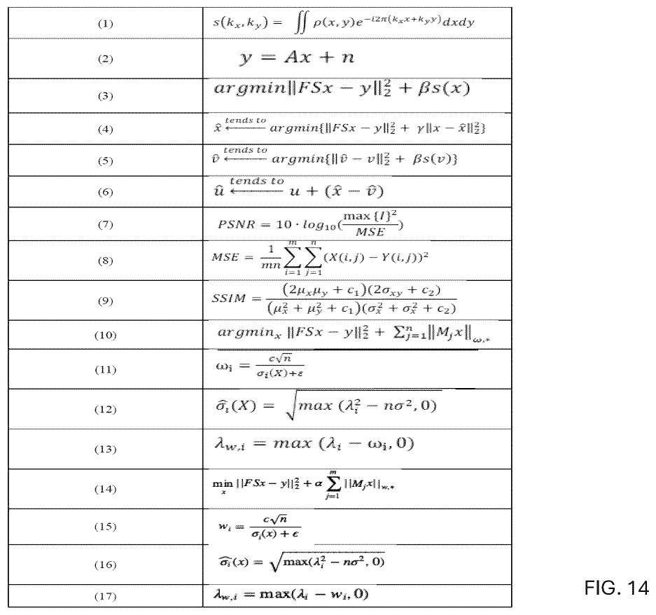

For MRI reconstruction, the collected signal can be written as Formula (1) of FIG. 14, which can be written in matrix form as Formula (2) of FIG. 14. In this model, variable “y” is the collected data and variable “x” is the expected image; “A” represents the sensor matrix; and “n” is the noise. In MRI, reconstruction of under-sampled data with a regularization term generally is written as Formula (3) of FIG. 14.

For purposes of this disclosure, A is replaced by a sensitivity map weighted operator and a Fourier transform. The PnP-ADMM framework decouples data fidelity and the prior term by splitting variable x into new variables x, v and u, and its augmented Lagrangian for MRI reconstruction is set forth as:

$$Ly ( x , u , v ) = {{‖ FSx - y ‖}^{2}}_{2} + β s ( v ) + λ {{‖ x + u - v ‖}^{2}}_{2} - λ {{‖ u ‖}^{2}}_{2} .$$

Next, this disclosure repeats the steps set forth in FIG. 14 as Formulas (4), (5), and (6) until convergence according to the ADMM algorithm, in which x\hat{ }=v\hat{ }−u, v\hat{ }=x\hat{ }+u.

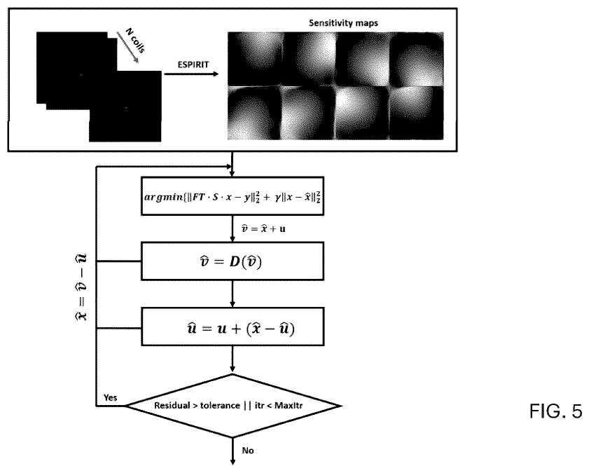

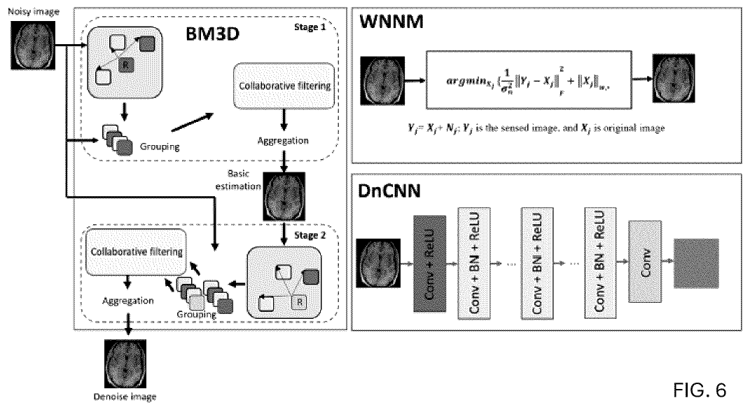

Here, FIG. 14, Formula (4) is a simple MAP estimate of x with the given data y, and Formula (5) is a denoising process. The data structure is amenable to plugging in advanced denoising algorithms. In this work, Formula (5) was achieved with BM3D, WNNM and DnCNN. The flowchart of PnP algorithm is illustrated in FIG. 5, and the briefly review of the three denoising algorithms is shown in FIG. 6.

Notice that previous methods have used real and imaginary data as the input to the denoising algorithm. Here, this disclosure explored that using magnitude data and phase data leads to better performance in PnP algorithm. BM3D, WNNM and DnCNN algorithms are downloaded online [12, 13, 14]. The tested data is from NYU fast MRI dataset [11] and the displayed brain data and ESPIRIT reconstruction are from Lustig's ESPIRIT demonstration [15]. An under-sampled pattern is generated with variable density Poisson distribution. Image qualities were evaluated with two indexes: peak signal-to-noise ratio (PSNR) and structural similarity index (SSIM), which are defined as follows:
where X is original image and Y is noisy image with M-by-N matrix size. μx and μy are the average of image X and Y respectively. σx² and σy² are variances of X and Y, and oxy represents covariance of X and Y. c₁ and c₂ are two variables to stabilize the division with a weak denominator.

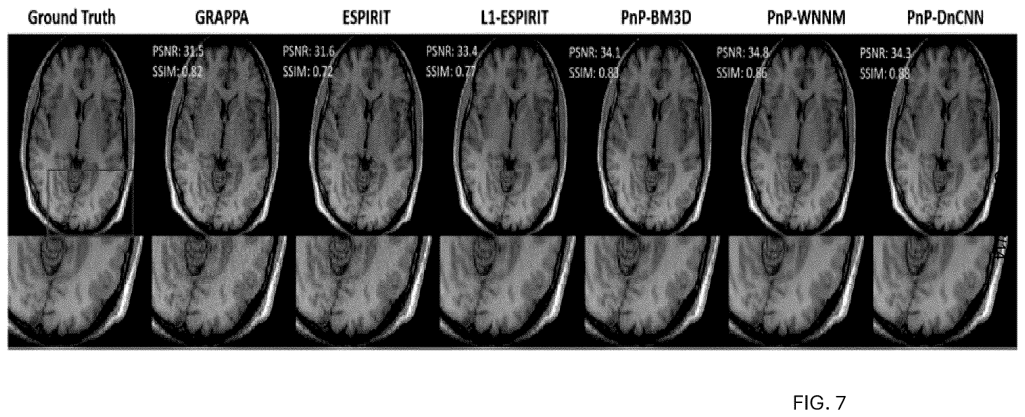

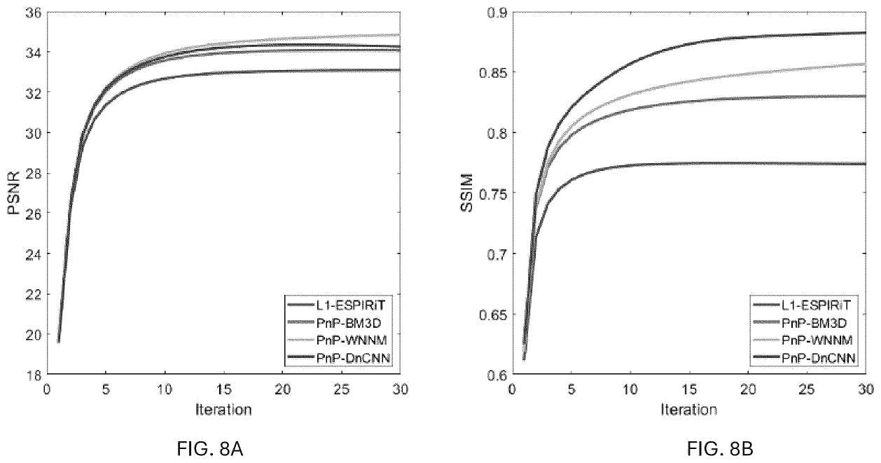

FIG. 7 and FIG. 8A, and 8B compare the PSNR and SSIM of the proposed three PnP-based methods and conventional methods with Cartesian data and an acceleration rate R=4. Even though images reconstructed with GRAPPA suffer from noise, its SSIM is still high compared to ESPIRIT-based methods in which noise were indeed suppressed, but structural similarity decreased. In the PnP-based methods, both PSNR and SSIM have been improved. PnP-DnCNN preserved the best structure information while PnP-WNNM achieved highest PSNR among the PnP-based method.

MR reconstruction with advanced denoising algorithms under the PnP-ADMM framework is a flexible approach for image reconstruction. In this study, the approach outperformed conventional regularization methods in MRI at acceleration rate R=4.

In another non-limiting embodiment, a nonconvex low rank regularization (NLR 900) was proposed to accelerate parameter mapping in the k-p domain. The NLR uses weighted nuclear norm minimization (WNNM 925) to obtain an optimized solution by differently penalizing singular values, in comparison to traditional low rank methods. The performance of the proposed algorithm was demonstrated for T2 mapping of the kidney in non-limiting examples. This disclosure demonstrated that the proposed algorithm outperformed k-p domain based compressed sensing and L&S algorithms.

Parameter mapping plays an important clinical role in improving the characterization of pathologies. However, multiple data acquisitions with different imaging parameters for T1/T2 mapping take considerable time. Longer scan times can cause drawbacks such as high cost, patient discomfort, and risk of bulk motion. To accelerate parameter mapping, under-sampling can be performed in the ky−p domain; however, this renders the image reconstruction an ill-posed inverse problem. Many methods [1-6] have been proposed to accelerate T1/T2/T2* mapping. Sparsity and low rank [1-3] prior information are commonly used. In addition, deep learning methods have recently been proposed to learn prior information for T2 mapping [6]. Compared to the traditional methods, deep learning methods require long training time and are highly dependent on specific acquisition settings. One of the goals of this study is to make better use of the low rank prior information to improve the estimation of parameter maps at highly under-sampled rates.

### Methods and Related System

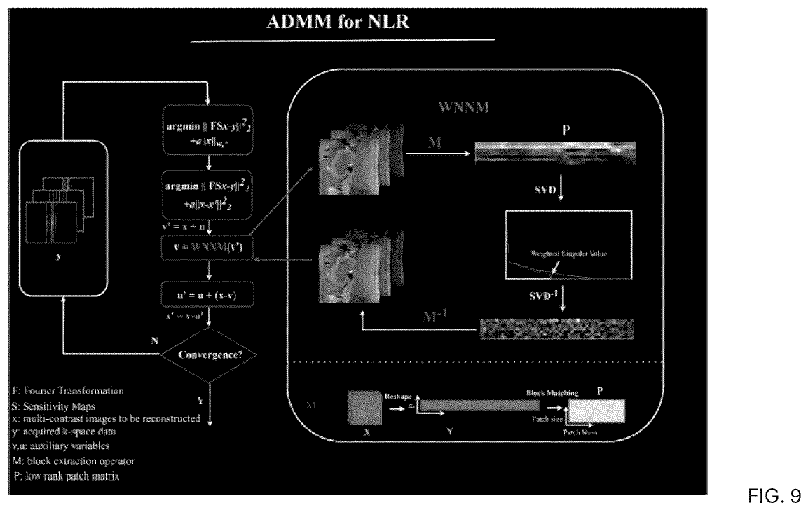

For reconstruction-based methods, multi-contrast images are usually first reconstructed from under-sampled k-space data and then the T1/T2/T2* mappings are estimated from exponential fitting. The two typical reconstruction-based methods are compressed sensing [1] (CS), which exploits the sparsity of the k-p domain, and low rank and sparse [2] (L&S), which utilizes both low rank and sparsity prior information to better facilitate T1/T2/T2* mapping. However, traditional low rank methods treat each singular value equally during the SVD operation to pursue a convex objective function, limiting its performance. Nonconvex regularized low rank is based on the fact that singular values of SVD 940 in low rank methods should be treated differently according to prior information namely, large singular values should be shrunk less to preserve the major data components. Therefore, a nonconvex low rank constraint for reconstruction-based parameter mapping can be written as Formula (10) in FIG. 14, where x represents the multi-contrast images 915 to be reconstructed, and y denotes the acquired data 902. S are the sensitivity maps 920, F indicates the Fourier transformation 925, Mj is a block operator 935 which is illustrated in FIG. 9, and |·|_{w,*} is the weighted nuclear norm 940, in which small singular values should have larger penalties. Hence the weights are set to be inversely proportional to the singular values according to Formula (11) of FIG. 14, where ωᵢ is the weight of the i^{th} singular value of the low-rank patch matrix Pj. Variable c is a constant, n is the number of similar patches in Pj, and ε is 10⁻¹⁶ [18, 19] to avoid division by 0. The variable σi (X) is the i^{th} singular value of artifact-free P\hat{ }j which is estimated as Formula 12 in FIG. 14 where lambda and sigma squared are the i^{th} singular value and the noise variance of Pj, respectively.

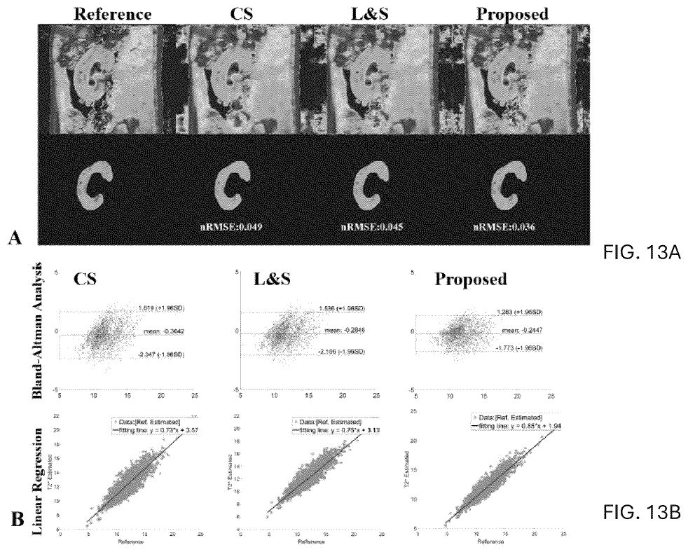

According to WNNM [22], the globally optimal solution of the nonconvex low-rank regularized objective function will be reached if the weights are in a non-ascending order, and the i^{th} weighted singular value λw,i calculated by the generalized soft-thresholding operator set forth in Formula (13) in FIG. 14. The ADMM method is used to solve this nonconvex problem. To accelerate the convergence of the non-local low-rank regularization (NLR) algorithm, the initial values are provided by the results of compressed sensing (CS). FIGS. 13A, 13B illustrate the ADMM framework for solving the NLR method.

In one non-limiting embodiment, the non-local low-rank regularization (NLR) of this disclosure was tested on T2w/T2*w k-space data of the kidney [8]. There were seven/ten echo times (TEs) in this data: (n1×10) ms for T2w data and (1.43+n2×2.14) ms for T2*w data, with a matrix size of 169×215. Retrospective under-sampling was performed in Ky−p domain (under-sampling rate=3,4,5,6) using a 2D variable density random pattern with four ky lines per echo fully sampled in the center of k-space.

### Results

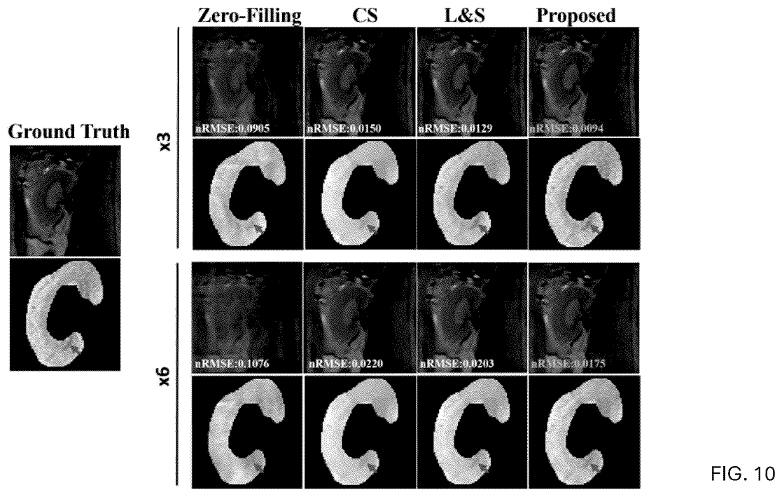

FIG. 10 shows that compared to CS and L&S, the proposed NLR achieves the lowest NRMSE of 0.0094 at R=3 and 0.0175 at R=6. The selected kidney ROIs show that the NLR better recovers the details of T2w images as indicated by the black arrows.

FIG. 7 displays the NRMSE and SSIM performance of the reconstructed T2w images at different under-sampling rates (R=3,4,5,6) using the proposed NLR method, CS and L&S. The proposed NLR method achieved the lowest NRMSE and highest SSIM at each under-sampling rate.

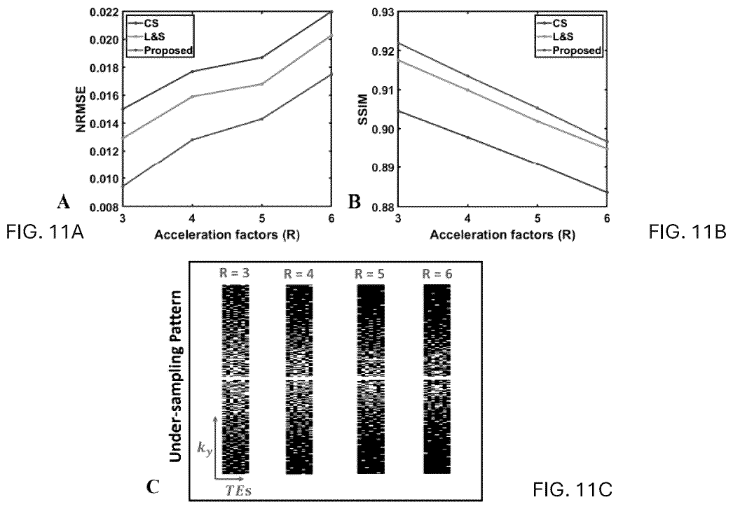

FIG. 10 and FIG. 11A show the high T2/T2* mapping performance of the proposed NLR in the selected ROI, whose NRMSE is 0.040/0.036, compared to 0.050/0.049 for CS and 0.048/0.045 for L&S. FIG. 8B and FIG. 9 show the proposed NLR has a stronger positive correlation with the reference T2/T2* mapping than CS and L&S under Bland-Altman analysis and linear regression. FIG. 11B shows the structural similarity index (SSIM) performance among compressed sensing (CS), low rank and sparse sampling (L&S) and non-local low-rank regularization (NLR). FIG. 11C displays the under-sampling patterns at different acceleration factors.

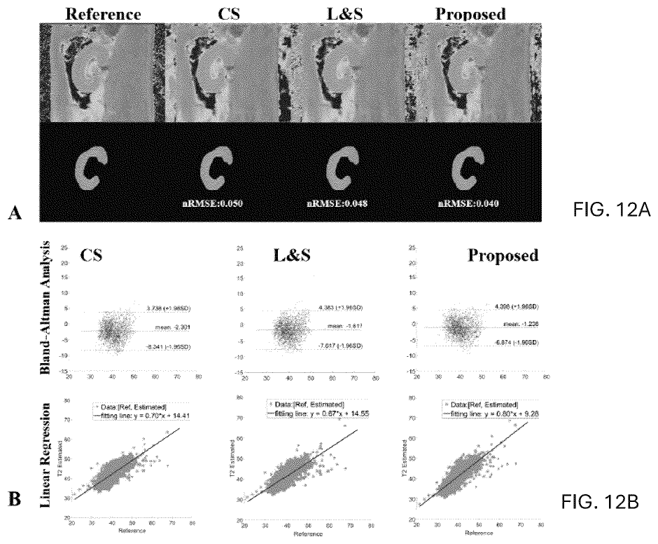

FIG. 12A shows a comparison of the results of T2 mapping using CS, L&S and NLR. FIG. 12A also shows the calculated T2 maps and selected ROI for quantitative analysis.

FIG. 12B displays the statistical results using Bland-Altman analysis and linear regression between the T2 maps estimated from CS, L&S and NLR vs. the reference T2 maps. NLR has stronger positive correlation than CS and L&S.

FIG. 13A illustrates a comparison of the results of T2* mapping using CS, L&S and NLR. FIG. 13A also shows the calculated T2 maps and selected ROI for quantitative analysis.

FIG. 13B displays the statistics results using Bland-Altman analysis and linear regression between the T2 maps estimated from CS, L&S and NLR vs. the reference T2 maps. NLR has stronger positive correlation than CS and L&S.

The NLR method (and related system) is proposed for accelerating parameter mapping in k-p domain, and it has better performance than CS and L&S, as demonstrated by the lowest NRMSE and highest SSIM of T2w/T2*w images at different acceleration rates and the strongest positive correlation between the estimated T2/T2*w maps and reference T2/T2* maps in statistical analysis. These initial results demonstrate that weighting singular values differently is a promising method for accelerated T2/T2* mapping.

In non-limiting examples, a nonconvex low rank regularization (NLR) was proposed to accelerate parameter mapping in the k-p domain. The NLR uses weighted nuclear norm minimization (WNNM) to obtain an optimized solution by differently penalizing singular values, in comparison to traditional low rank methods. The performance of the proposed algorithm was demonstrated for T2 mapping of the kidney. One non-limiting study demonstrated that the proposed algorithm outperformed k-p domain-based compressed sensing and L&S algorithms.

A nonconvex low rank regularization (NLR) was proposed to accelerate parameter mapping in the k-p domain. The NLR uses weighted nuclear norm minimization (WNNM) to obtain an optimized solution by differently penalizing singular values, in comparison to traditional low rank methods. The performance of the proposed algorithm was demonstrated for T2 mapping of the kidney. One non-limiting study demonstrated that the proposed algorithm outperformed k-p domain-based compressed sensing and L&S algorithms.

### EXAMPLE EMBODIMENTS

In one embodiment, a computer implemented method 400 of reconstructing magnetic resonance images (MRI) in Cartesian coordinates uses acquired magnetic resonance data 405 and implements a Fourier transform 410 to place the MRI data in k-space. In some examples, the method may apply a sensitivity map weighted operator to the k-space data 415. The method allows for under-sampling the k-space 420 and achieving an accurate output image by selecting an image model to map the sampled data and iteratively converge variables in the model (i.e., optimize the variables 425) to an output image 435 that matches a region of interest subject to the MRI. The image model may be an alternating direction method of multipliers (ADMM) or an ADMM with non-convex low rank regularization algorithm. The method may include utilizing a de-noising algorithm 430 which may be at least one of a plug and play block matching and 3D filtering (PnP-BM3D), a plug and play weighted nuclear norm minimization (WNNM), or a plug and play denoising convolutional neural networks (PnP-DnCNN) algorithm. Machine learning allows for an iterative optimization of the variables of the model and yields an output image.

In one non-limiting embodiment, a computer implemented method of reconstructing a magnetic resonance image in Cartesian space, with a computer having a processor, computer memory, and software configured to implement image processing functions, includes acquiring magnetic resonance image (MRI) data for a region of interest of a subject 200; calculating a Fourier transform of the MRI data and saving Fourier transform data in the memory 505; applying a sensitivity map weighted operator to the Fourier transform data 510; modeling an expected image from the Fourier transform data according to variables to be estimated (515, 520, 525). In some non-limiting embodiments, the variables to be estimated are three variables that are present in a Lagrangian model of the Fourier transform data. An iterative process for reconstructing the magnetic resonance image in Cartesian coordinates from the Fourier transform data includes converging the variables to respectively selected estimates with an alternating direction method of multipliers (ADMM) procedure 905; and saving an output image in Cartesian coordinates after estimating the three variables for respective portions of the Fourier transform data 950. Each section, portion, patch, voxel or pixel within the Fourier transform data, can be modeled according to variables of a model. Without limiting this disclosure to any one model, a Lagrangian model utilizes three variables, i.e., the above noted x, v and u, to be estimated according to the resolution that the user desires.

In another embodiment, the computer implemented method includes applying at least one de-noising algorithm 600 to Fourier transform data when converging the three variables to a selected estimate. The de-noising algorithm may be at least one of a plug and play block matching and 3D filtering (PnP-BM3D 620), a plug and play weighted nuclear norm minimization (WNNM 625), or a plug and play denoising convolutional neural networks (PnP-DnCNN 630) algorithm. The Fourier transform data may include magnitude data and phase data for the MRI data.

Estimating the variables, such as the above noted three Lagrangian variables, may be an iterative process 500 of calculating estimates of the MRI data across a sampled portion 501 of the Fourier transform data 550, applying a de-noising algorithm 600, and calculating another estimate of the sampled portion of the expected image. In the example Lagrangian model, estimating the three variables includes iteratively cycling through machine learning algorithms to converge the ADMM procedure to a solution. As shown in FIG. 5, the iterations continue so long as a residual image value is greater than a pre-set tolerance and the number of iterations is less than a pre-set maximum of iterations. In the method of this disclosure, the output image may be required to meet or exceed pre-set values for peak signal to noise ratio or structural similarity measurements.

In another embodiment, a computer implemented method of reconstructing a magnetic resonance image in Cartesian space utilizes a computer having a processor, computer memory, and software configured to implement image processing functions. The method includes acquiring magnetic resonance image (MRI) data for a region of interest of a subject; calculating a Fourier transform of the MRI data and saving Fourier transform data in the memory; applying a sensitivity map weighted operator to the Fourier transform data; modeling an expected image according to variables of a non-convex low rank regularization algorithm to be estimated for reconstructing the magnetic resonance image in Cartesian coordinates from the Fourier transform data; estimating the variables for respective portions of the Fourier transform data with an alternating direction method of multipliers (ADMM) algorithm; and saving an output image in Cartesian coordinates after optimizing the three variables. In this non-limiting embodiment, the method may further utilize a weighted nuclear norm minimization (WNNM) process to converge estimates of the variables within the chosen model. Utilizing a weighted nuclear norm minimization (WNNM) process enhances singular values within the Fourier transform data that exceed a threshold for being a large value. Utilizing a weighted nuclear norm minimization (WNNM) process penalizes other singular values within the Fourier transform data that are lower than a threshold for being a small value. The non-convex model allows for under-sampling the Fourier transform data in a k-parameter space (K-p) and then estimating the values necessary to complete a Cartesian reconstruction of the MRI with less data processing. The method utilizes an iterative loop as shown in FIG. 9 to estimate the model variables, with proper accuracy, for selected portions, patches, sections, voxels or pixels from the Fourier transform data. In some embodiments, compressed sensing (CS) is used to set initial values of the variables and then progressing with the iterative loop from that initial value. Estimating the variables may utilize a machine learning process until the machine learning process converges to the output image.

These and other aspects of the disclosure are further set forth in the claims and the figures herein.

### REFERENCES

The following patents, applications and publications as listed below and throughout this document are hereby incorporated by reference in their entirety herein, and which are not admitted to be prior art with respect to the present invention by inclusion in this section.
[1] Pruessmann K P, et al. MRM 1999; 42:952-962.
[2] Griswold M A, et al. MRM 2002; 47:1202-1210.
[3] Lustig M, et al. MRM 2007; 58:1182-1195.
[4] Uecker M, et al. MRM 2014; 71:990-1001.
[5] Venkatakrishnan S V, et al. IEEE GlobalSIP 2013; 945-948.
[6] Ahmad R, et al. IEEE SPM 2020; 37:105-116.
[7] Yazdanpanah A P, et al. IEEE ICCV; 2019
[8] Zhang K, et al. IEEE TIP 2017; 26:3142-3155.
[9] Dabov K, et al. IEEE TIP 2007; 16:2080-2095.
[10] Gu S H, et al. IEEE CVPR 2014; 2862-2869.
[11] https://fastmri.med.nyu.edu/
[12] https://webpages.tuni.fi/foi/GCF-BM3D/
[13] https://github.com/csjunxu/WNNM_CVPR2014
[14] https://github.com/cszn/DnCNN
[15] https://people.eecs.berkeley.edu/˜mlustig/Software.html
[16] Doneva M et al. MRM. 2010; 64(4): 1114-1120.
[17] Zhao B et al. MRM. 2015; 74(2): 489-498.
[18] Zhang T et al. MRM. 2015; 73:655-661.
[19] Zhao L et al. MRM. 2016; 75:1989-1999.
[20] Liu F et al. MRM. 2018; 82(1): 174-188.
[21] Meng Z Y et al. MRM. 2020;
[22] Gu S H et al. IEEE CVPR. 2014; 978(1): 4799-5118
[23] https://github.com/JoaoPeriquito/T2-s-Mapping
[24] Guillemot V., et al., (2019) A constrained singular value decomposition method that integrates sparsity and orthogonality. PLOS ONE 14(3): e0211463. https://doi.org/10.1371/journal.pone.0211463.
[25] Lyra-Leite, D. M., da Costa, J. P. C. L. and Carvalho, J. L. A. “Improved MRI Reconstruction Using a Singular Value Decomposition Approximation”. In: Ingeniería, Vol. 17, No. 2, page 35-45.

### CONCLUSION

The specific configurations, choice of materials and the size and shape of various elements can be varied according to particular design specifications or constraints requiring a system or method constructed according to the principles of the disclosed technology. Such changes are intended to be embraced within the scope of the disclosed technology. The presently disclosed embodiments, therefore, are considered in all respects to be illustrative and not restrictive. The patentable scope of certain embodiments of the disclosed technology is indicated by the appended claims, rather than the foregoing description.

1. A computer implemented method of reconstructing a magnetic resonance image in Cartesian space with a computer having a processor, computer memory, and software configured to implement image processing functions, the method comprising:
acquiring magnetic resonance image (MRI) data for a region of interest of a subject;
calculating a Fourier transform of the MRI data and saving Fourier transform data in the memory;
applying a sensitivity map weighted operator to the Fourier transform data;
modeling an expected image from the Fourier transform data according to variables to be estimated for reconstructing the magnetic resonance image in Cartesian coordinates from the Fourier transform data;
converging the variables to respectively selected estimates with an alternating direction method of multipliers (ADMM) procedure; and
saving an output image in Cartesian coordinates after estimating the variables for respective portions of the Fourier transform data.

2. The computer implemented method of claim 1, further comprising applying at least one de-noising algorithm to Fourier transform data when converging the variables to a selected estimate.

3. The computer implemented method of claim 2, wherein the de-noising algorithm comprises at least one of a plug and play block matching and 3D filtering (PnP-BM3D), a plug and play weighted nuclear norm minimization (WNNM), or a plug and play denoising convolutional neural networks (PnP-DnCNN) algorithm.

4. The computer implemented method of claim 1, wherein the Fourier transform data comprises magnitude data and phase data for the MRI data.

5. The computer implemented method of claim 1, wherein the variables to be estimated are components of an augmented Lagrangian model of the expected image to be reconstructed from the Fourier transform data.

6. The computer implemented method of claim 1, wherein estimating the variables comprises an iterative process of calculating estimates of the MRI data across a portion of the Fourier transform data, applying a de-noising algorithm, and calculating another estimate of the portion of the expected image.

7. The computer implemented method of claim 6, wherein estimating the variables comprises iteratively cycling through machine learning algorithms to converge the ADMM procedure to a solution.

8. The computer implemented method of claim 7, wherein the iterations continue so long as a residual image value is greater than a pre-set tolerance and the number of iterations is less than a pre-set maximum of iterations.

9. The computer implemented method of claim 8, wherein saving the output image comprises meeting or exceeding pre-set values for peak signal to noise ratio or structural similarity measurements.

10. A computer implemented method of reconstructing a magnetic resonance image in Cartesian space with a computer having a processor, computer memory, and software configured to implement image processing functions, the method comprising:
acquiring magnetic resonance image (MRI) data for a region of interest of a subject;
calculating a Fourier transform of the MRI data and saving Fourier transform data in the memory;
applying a sensitivity map weighted operator to the Fourier transform data;
modeling an expected image according to variables of a non-convex low rank regularization algorithm to be estimated for reconstructing the magnetic resonance image in Cartesian coordinates from the Fourier transform data;
estimating the variables for respective portions of the Fourier transform data with an alternating direction method of multipliers (ADMM) algorithm; and
saving an output image in Cartesian coordinates after estimating the variables.

11. The computer implemented method of claim 10, further comprising utilizing a weighted nuclear norm minimization (WNNM) process to converge estimates of the variables.

12. The computer implemented method of claim 11, wherein utilizing a weighted nuclear norm minimization (WNNM) process enhances singular values within the Fourier transform data that exceed a threshold for being a large value.

13. The computer implemented method of claim 11, wherein utilizing a weighted nuclear norm minimization (WNNM) process penalizes other singular values within the Fourier transform data that are lower than a threshold for being a small value.

14. The computer implemented method of claim 10, further comprising under-sampling the Fourier transform data in a k-parameter space (K-p).

15. The computer implemented method of claim 10, further comprising utilizing compressed sensing to set initial values of the variables.

16. The computer implemented method of claim 15, iteratively optimizing the variables with a machine learning process until the machine learning process converges to the output image.

17. A computerized system of reconstructing a magnetic resonance image in Cartesian space, the system comprising:
a computer having a processor, computer memory, and software configured to implement image processing functions, wherein the software includes computer implemented instructions to perform a method comprising:
acquiring magnetic resonance image (MRI) data for a region of interest of a subject;
calculating a Fourier transform of the MRI data and saving Fourier transform data in the memory;
applying a sensitivity map weighted operator to the Fourier transform data;
modeling an expected image according to variables of a non-convex low rank regularization algorithm to be estimated for reconstructing the magnetic resonance image in Cartesian coordinates from the Fourier transform data;
estimating the variables for respective portions of the Fourier transform data with an alternating direction method of multipliers (ADMM) algorithm; and
saving an output image in Cartesian coordinates after estimating the variables.
